(19) United States
(12) Patent Application Publication
(10) Pub. No.: US 2025/0035713 A1
(43) Pub. Date: Jan. 30, 2025

(54) SYSTEM AND METHOD FOR SENSING ONE OR MORE POWER LINES

(71) Applicant: ACLARA TECHNOLOGIES LLC, St. Louis, MO (US)

(72) Inventor: Douglas Hamilton, Arlington Heights, IL (US)

(21) Appl. No.: 18/916,888

(22) Filed: Oct. 16, 2024

Related U.S. Application Data
(63) Continuation of application No. 17/011,402, filed on Sep. 3, 2020, now Pat. No. 12,130,339.
(60) Provisional application No. 62/896,201, filed on Sep. 5, 2019.

(51) Int. Cl. G01R 31/52; G01R 31/08

(52) U.S. Cl. CPC G01R 31/52; G01R 31/085

(57) ABSTRACT

A power line sensor including a housing and a near field sensor. The housing is configured to couple to a power line. The near field sensor is configured to sense a leakage current on the power line.

### RELATED APPLICATIONS

This application claims priority to U.S. patent application Ser. No. 17/011,402, filed Sep. 3, 2020, which claims priority to U.S. Provisional Patent Application No. 62/896,201, filed Sep. 5, 2019, the disclosure of which is incorporated herein by reference in its entirety.

### FIELD

Embodiments relate to power line sensors.

### SUMMARY

Power line events may be detected by sensing partial discharge, which may be a low leakage current from a primary through a path of least resistance to ground. Early detection of low leakage current may be used to correct and prevent power line events before they occur. Leakage current may be detected via ground based and/or aerial assessments. However, such assessments may be overly expensive and timely.

Thus, one embodiment provides a power line sensor including a housing and a near field sensor. The housing is configured to couple to a power line. The near field sensor is configured to sense a leakage current on the power line.

Another embodiment provides a method of determining a potential event of a power line. The method includes sensing, via a near field sensor, a leakage current on the power line. The method further includes determining, via an electronic processor, a potential event based on the leakage current on the power line.

Yet another embodiment provides a system for determining a potential event on a power line. The system includes a first line sensor, a second line sensor and an electronic processor. The first line sensor includes a first near field sensor configured to sense a first leakage current at a first location on the line. The second line sensor includes a second near field sensor configured to sense a second leakage current at a second location on the line. The electronic processor is configured to receive data corresponding to the first leakage current and the second leakage current, and determine a location of a potential event on the line based on the data.

Other aspects of the application will become apparent by consideration of the detailed description and accompanying drawings.

### BRIEF DESCRIPTION OF THE DRAWINGS

FIG. 1 illustrates a utility distribution system according to some embodiments.

FIG. 2 is a block diagram illustrating a line sensor configured to sense one or more characteristics of a line of the utility distribution system of FIG. 1 according to some embodiments.

FIG. 3 is a block diagram illustrating a line sensing system configured to sense one or more characteristics of the utility distribution system of FIG. 1 according to some embodiments FIGS. 4A-4C illustrate line sensors according to some embodiments.

FIG. 5 is a flowchart illustrating a process of sensing one or more characteristics of the utility distribution system of FIG. 1.

### DETAILED DESCRIPTION

Before any embodiments of the application are explained in detail, it is to be understood that the application is not limited in its application to the details of construction and the arrangement of components set forth in the following description or illustrated in the following drawings. The application is capable of other embodiments and of being practiced or of being carried out in various ways.

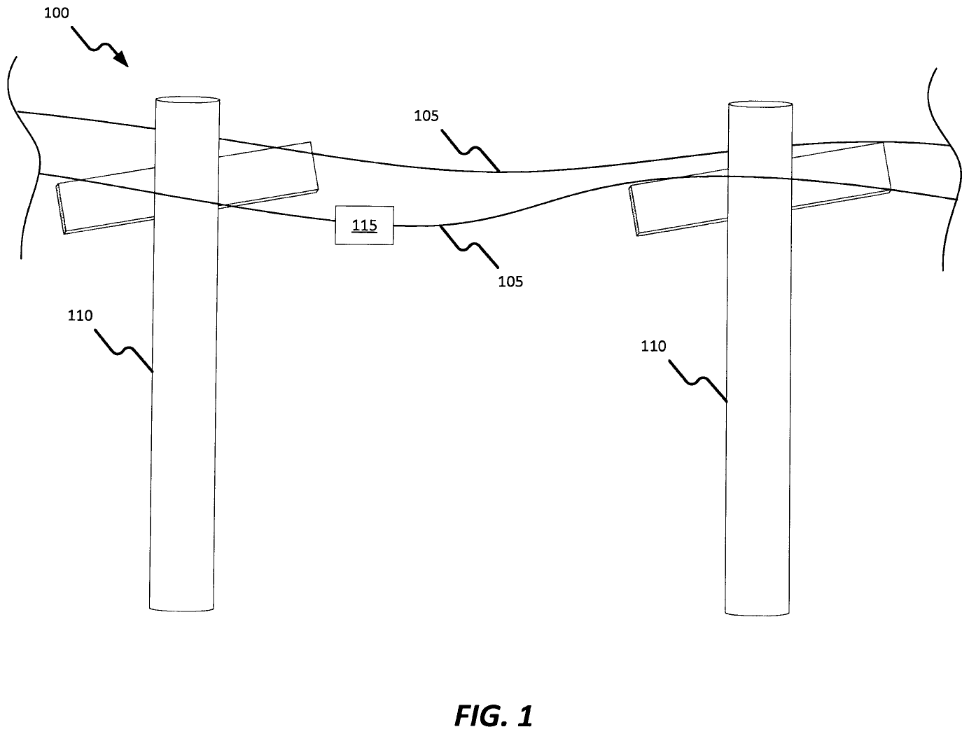

FIG. 1 illustrates a utility distribution system 100 according to some embodiments. In the illustrates embodiment, the system 100 includes one or more power lines 105 supported by one or more utility poles 110. Although illustrated as being supported by utility poles 110, in other embodiments, the power lines 105 may be underground and/or supported by other structures (for example, buildings). The system 100 may further include a line sensor 115.

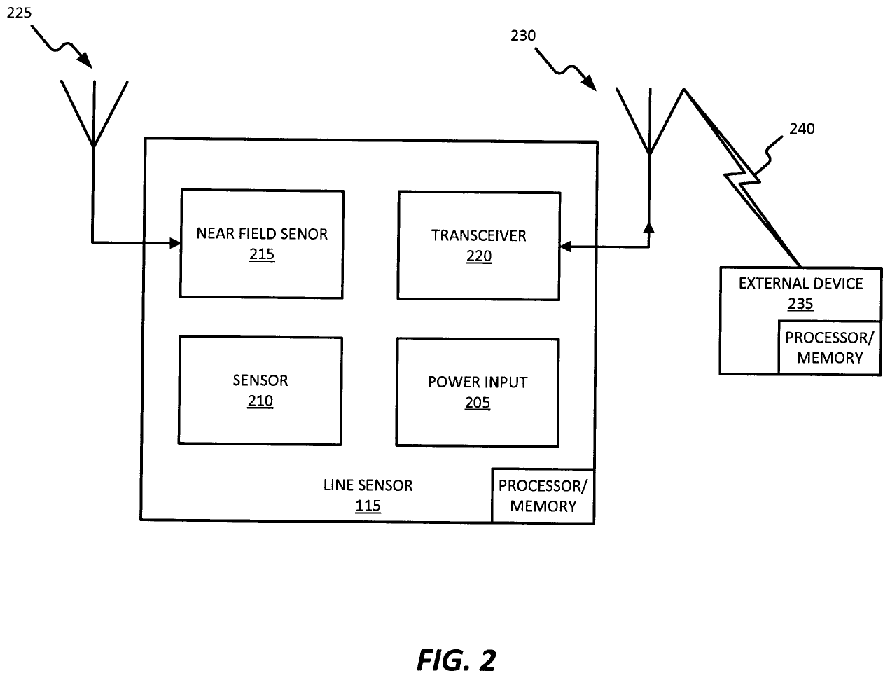

FIG. 2 is a block diagram of the line sensor (such as, but not limited to, a power line sensor) 115 according to some embodiments. The line sensor 115 may be configured to couple directly onto the line 105 and sense one or more characteristics of the line 105. In some embodiments, the line sensor 115 is coupled to the line 105 by clamping around the line 105.

In the illustrated embodiment, the line sensor 115 includes a power input 205, a characteristic sensor 210, a near field sensor 215, and a transceiver 220. In some embodiments, the line sensor 115 further includes an electronic processor and a memory. The electronic processor and/or memory may be configured to provide signal conditioning and/or detecting. The power input 205 may be configured to receive power from line 105, convert the line power to a nominal power, and provide power to other components and/or modules of the line sensor 115.

The characteristic sensor 210 may be configured to sense one or more characteristics of the line 105. In some embodiment, the sensed characteristics include electrical characteristics, such as but not limited to, a line voltage and a line current. In some embodiments, the sensed characteristics include one or more temperatures, such as but not limited to, a line temperature and/or an ambient temperature. In some embodiments, the sensed characteristics include an inclination and/or an amount of line sagging, wind movement, electrical fields, power generation, and/or distribution and consumption of electricity.

The near field sensor 215 may be configured to detect a leakage current of line 105. The leakage current of line 105 may be a leakage current from a primary of the line 105 through a path of least resistance to ground. In some embodiments, the near field sensor 215 detects the leakage current by sensing, a discharged, or partial discharge, radio frequency from line 105. As illustrated, in some embodiments, the near field sensor 215 senses the discharged radio frequency via a near field antenna 225.

In some embodiments, the near field sensor 215 is a conductive sensor. In some embodiments, the near field sensor 215 is an electromagnetic sensor. In such an embodiment, the near field sensor 215 may sense the leakage current via electromagnetic radiation sensing (or radiation sensing), radio frequency sensing, light sensing (for example, ultraviolet sensing, infrared sensing, etc.), and/or thermal sensing. In some embodiments, the near field sensor 215 is an acoustic sensor. In such an embodiment, the near field sensor 215 may sense the leakage current via audio sensing (for example, apparatus (such as, but not limited to audio sensors) and methods disclosed in U.S. Pat. No. 10,440,472, hereby incorporated by reference) and/or ultrasonic sensing. In some embodiments, the near field sensor 215 is a gas sensor. In such an embodiment, the near field sensor 215 may sense the leakage current via ozone sensing and/or nitrous oxide sensing.

The transceiver 220, along with a transceiver antenna 230, may be configured to enable wireless communication to/from the line sensor 115. In other embodiments, rather than a transceiver 220 and transceiver antenna 230, the line sensor 115 may include separate transmitting and receiving components, for example, a transmitter, a transmitting antenna, a receiver, and a receiving antenna. In some embodiments, the transceiver 220 may be configured to enable wired communication to/from the line sensor 115.

The line sensor 115, via the transceiver 220, may communicate with an external device 235. In some embodiments, the line sensor 115 wirelessly communicates with the external device via a communication link 240. In some embodiments, the communication link 240, for example, a wide area network (WAN) (e.g., a transport control protocol/internet protocol (TCP/IP) based network, a cellular network, such as, for example, a Global System for Mobile Communications (or Groupe Spécial Mobile (GSM)) network, a General Packet Radio Service (GPRS) network, a Code Division Multiple Access (CDMA) network, an Evolution-Data Optimized (EV-DO) network, an Enhanced Data Rates for GSM Evolution (EDGE) network, a 3GSM network, a 4GSM network, a Digital Enhanced Cordless Telecommunications (DECT) network, a Digital advanced mobile phone system (AMPS) (IS-136/time division multiple access (TDMA)) network, or an Integrated Digital Enhanced Network (iDEN) network, etc.). In other embodiments, the communication link 240 is, for example, a local area network (LAN), a neighborhood area network (NAN), a home area network (HAN), or personal area network (PAN) employing any of a variety of communications protocols, such as Wi-Fi, Bluetooth, ZigBee, etc. Other wide area networks, such as land mobile radio (LMR), terrestrial trunked radio (TETRA), and digital mobile radio (DMR) may also be used. In some embodiments, the line sensor 115 uses one or more of the above communication protocols.

The external device 235 may be, but is not limited to, an external computer, one or more server(s), a smart telephone, a tablet, and/or a laptop. As illustrated, the external device 235 may be remote from the line sensor 115. The external device 235 may include an electronic processor and a memory. In one embodiment of operation, the external device 235 receives data corresponding to the one or more characteristics of the line 105 and/or the leakage current of the line 105. The external device 235 then analyzes the data to detect potential events that may occur on the line 105.

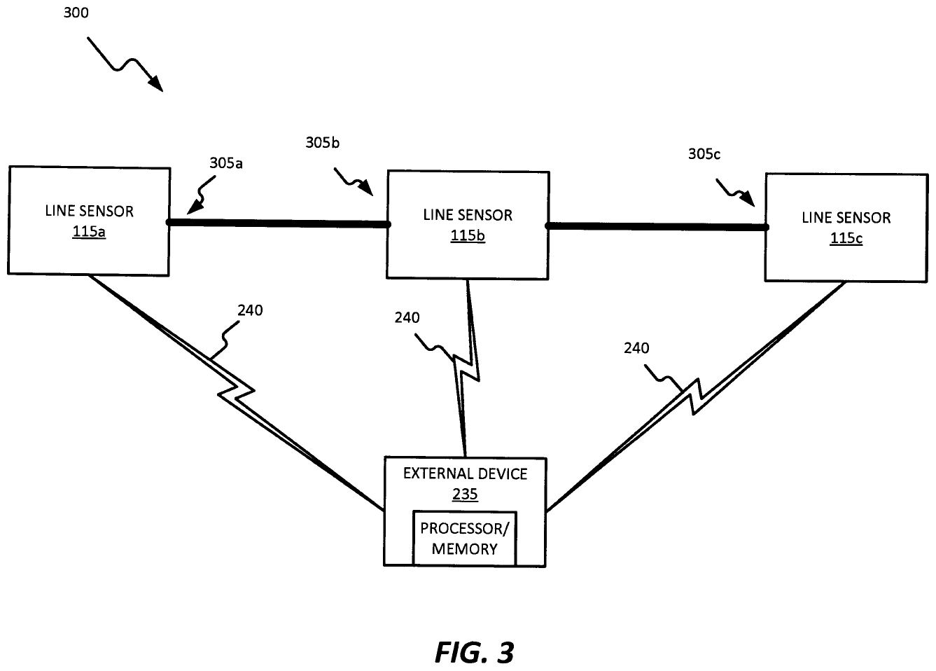

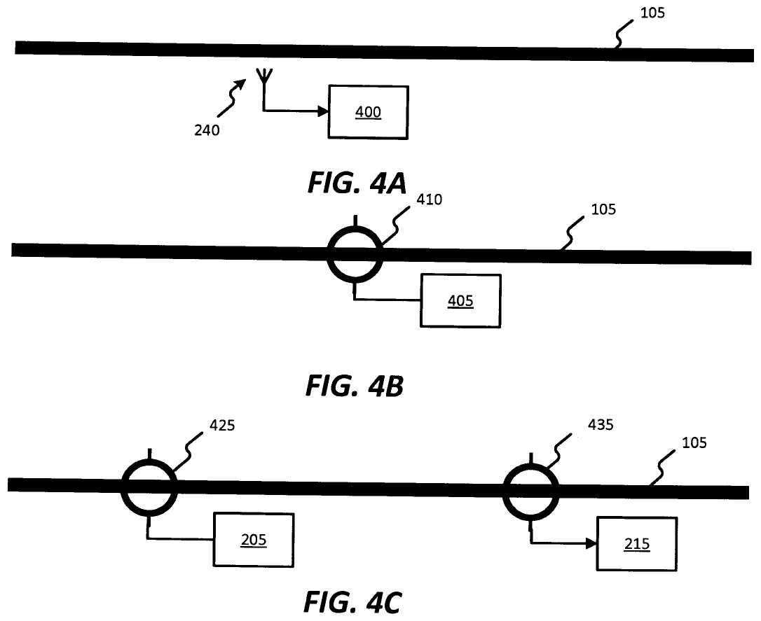

FIG. 3 is a block diagram illustrating a line sensing system 300 according to some embodiments. The system 300 may include one or more line sensors 115a, 115b, 115c coupled to the line 105 at various line portions 305a, 305b, 305c. In some embodiments, the various line portions 305 may be located at equal distances from each other and/or varying distances from each other. Although only illustrated as including three line sensors, in other embodiments the system 300 may include four or more line sensors. Each sensor 115a, 115b, 115c may be communicatively coupled to the external device 235, so that the external device 235 may receive data from each line sensor 115a, 115b, 115c.

In one embodiment of operation, the external device 235 receives data corresponding to leakage current at one or more of the various portions 305a, 305b, 305c on line 105 corresponding to locations of the sensors 115a, 115b, 115c. Based on the data from line sensors 115a, 115b, 155c, the external device 235 may determine a potential event and/or extrapolate the location of a potential event on the line 105. For example, a first leakage current detected by line sensor 115a having a greater magnitude than a second leakage current detected by line sensor 115b may correspond to a potential event occurring between line sensors 115a, 115b in an area closer to line sensor 115a than line sensor 115b. The external device 235 may then output alerts and/or notification of the potential event and/or the location of the potential event on the line 105.

FIG. 4A illustrates a line sensor 400 according to some embodiments. Line sensor 400 may include similar components and functionality as line sensor 115, including signal conditioning and/or detecting. Similar to line sensor 115, line sensor 400 may include a transceiver 220 configured to sense a leakage current of line 105 via near field sensing.

FIG. 4B illustrates a line sensor 405 according to some embodiments. Line sensor 405 may include similar components and functionality as line sensor 115, including signal conditioning and/or detecting. Line sensor 405 may include a current transformer (CT) 410 in addition to, or in lieu of, transceiver 220. In some embodiments, CT 410 is a coil wound around a core (for example, a toroidal ferrite core). The line 105 may pass through the core of CT 410. In one embodiment of operation, the CT 410 senses a leakage current and line sensor 405 performs signal conditioning and/or detection of the sensed leakage current. In some embodiments, CT 410 may receive power from line 105, as well as sense a leakage current on line 105.

FIG. 4C illustrates a line sensor 415 according to some embodiments. Line sensor 415 may include similar components and functionality as line sensor 115, including signal conditioning and/or detecting. Line sensor 415 may include a first CT 420 and a second CT 425. In some embodiments, first and second CTs 420, 425 may be substantially similar to CT 410. In one embodiment of operation, line sensor 415 may receive power via first CT 420 and supply the power to power input 205, while the second CT 425 may be used to sense a leakage current on line 105.

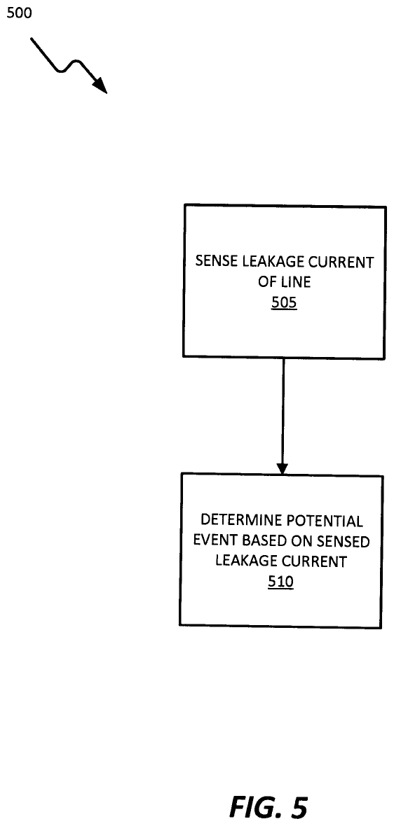

FIG. 5 illustrates an operation, or process, 500 according to some embodiments. Process 500 may be performed via line sensor 115, external device 235, line sensor 400, and/or system 300. A leakage current is sensed via a near field sensor (block 505). A potential event is determined based on the sensed leakage current (block 510).

Embodiments provide, among other things, a system and method for determining potential events on a power line. Various features and advantages of the application are set forth in the following claims.

What is claimed is:

1. A power line sensor comprising:
a housing configured to couple to a power line; and
a radiation sensor configured to sense a leakage current on the power line.

2. The power line sensor of claim 1, further comprising a transceiver configured to communicate with an external device.

3. The power line sensor of claim 2, wherein the power line sensor, via the transceiver, outputs the sensed leakage current to the external device.

4. The power line sensor of claim 3, wherein the external device determines a potential event based on the sensed leakage current to the external device.

5. The power line sensor of claim 4, wherein the external device outputs a notification based on the potential event.

6. A method of determining a potential event of a power line, the method comprising:
sensing, via a radiation sensor, a leakage current on the power line; and
determining, via an electronic processor, the potential event based on the leakage current on the power line.

7. The method of claim 6, further comprising:
coupling the radiation sensor to the power line.

8. The method of claim 6, wherein the electronic processor is remote from the radiation sensor.

9. The method of claim 6, wherein the radiation sensor is incorporated into a current transformer.

10. A system for determining a potential event on a power line, the system comprising:
a first line sensor including a first radiation sensor configured to sense a first leakage current at a first location on the line;
a second line sensor including a second radiation sensor configured to sense a second leakage current at a second location on the line; and
an electronic processor configured to
receive data corresponding to the first leakage current and the second leakage current, and
determine a location of the potential event on the line based on the data.

11. The system of claim 10, wherein the first radiation sensor and the second radiation sensor are incorporated into current transformers.

12. The system of claim 10, wherein the electronic processor is remote from at least one selected from a group consisting of the first line sensor and the second line sensor.

13. The system of claim 10, wherein the first radiation sensor is incorporated into a current transformer.
